(19) United States
(12) Patent Application Publication
(10) Pub. No.: US 2016/0033754 A1
(43) Pub. Date: Feb. 4, 2016

(54) DISPLAY DEVICE AND METHOD FOR FABRICATING THE SAME

(71) Applicant: InnoLux Corporation, Miao-Li County (TW)

(72) Inventors: Yu-Chung LIU, Miao-Li County (TW); Te-Yu LEE, Miao-Li County (TW); Chien-Ta HUANG, Miao-Li County (TW)

(21) Appl. No.: 14/806,931

(22) Filed: Jul. 23, 2015

(30) Foreign Application Priority Data
Aug. 1, 2014 (TW) 103126349

(51) Int. Cl. G02B 26/00; B81C 1/00

(52) U.S. Cl. CPC G02B 26/001; B81C 1/00198

(57) ABSTRACT

A display device and a method for fabricating the same are provided. The device is an active matrix interference modulator (IMOD) display device which includes a thin film transistor and an interference modulator (IMOD). The interference modulator (IMOD) is integrated on the thin film transistor, a first metal layer is simultaneously used as a light-shielding pattern and a gate electrode, and a second metal layer is simultaneously used as a wiring and a source/drain metal layer. Therefore, the fabricating time and cost are saved. In addition, the aperture ratio of the display device is improved because the pixel thin film transistor is not below an optical gap.

### CROSS REFERENCE TO RELATED APPLICATIONS

This Application claims priority of Taiwan Patent Application No. 103126349, filed on Aug., 1, 2014, the entirety of which is incorporated by reference herein.

### BACKGROUND

1. Field of the Disclosure

The present disclosure relates to a display device, and in particular, relates to a active matrix interference modulator (IMOD) display device.

2. Description of the Related Art

Consumer electronic applications are becoming increasingly diverse with the rapid progress of science and technology. In various electronic products, the liquid crystal displays are widely used, such as in personal computer, personal digital assistant (PDA), mobile phone or television, because it has several advantages including light, low power consumption, no radiation, etc.

The basic principle of the liquid crystal display (LCD) is that the intensity of the light is controlled by using the polarization of the liquid crystal after the light of a backlight source passing through the color filter. However, when the light passes through the color filter, the intensity of the light may be reduced. Therefore, a novel microelectro-mechanical system (MEMS display) has been developed.

In various microelectro-mechanical system, the interferometric modulator (IMOD) has several advantages including wide viewing angle, low power consumption, etc., considerable research attention has been recently focused on development thereof. The interferometric modulator (IMOD) is made of two parallel reflection surfaces composed of an air gap interposed therebetween. When the light is irradiated to this structure, a portion of the light is upwardly reflected, and a portion of the light passes through an upper portion of the transparent reflection surface into the air gap to form internal reflection. Therefore, various colors of the light are produced by using the interference of the light waves.

However, the current interferometric modulator (IMOD) display device development is not yet mature, still faces many challenges.

### BRIEF SUMMARY

The disclosure provides a display device. The display device includes a substrate, wherein the substrate comprises a display region and border region outside the display region; a light-shielding pattern, located in the display region; a pixel thin film transistor, located in the display region and comprising: a pixel gate electrode; a first insulating layer, disposed over the pixel gate electrode; an active layer, disposed over the first insulating layer; and a second metal layer, disposed over the active layer; a wiring, located in the border region; a peripheral thin film transistor located in the border region and comprising: a peripheral gate electrode; the first insulating layer, disposed over the peripheral gate electrode; the active layer, disposed over the first insulating layer; and the second metal layer, disposed over the active layer; wherein the light-shielding pattern, the pixel gate electrode, the wiring and the peripheral gate electrode are made by a first metal layer; a pixel electrode, disposed over the second metal layer and located in the display region; and an interference modulator (IMOD), disposed over the pixel electrode.

The disclosure also provides a method for fabricating a display device. The method includes providing a substrate, wherein the substrate comprises a display region and a border region outside the display region; forming a first metal layer in the display region and the border region, wherein the first metal layer in the border region is used as a peripheral gate electrode and a wiring, and the first metal layer in the display region is used as a pixel gate electrode and a light-shielding pattern; forming a first insulating layer over the first metal layer; forming an active layer over the first insulating layer; forming a second metal layer over the active layer, wherein the peripheral gate electrode, the first insulating layer, the active layer and the second metal layer located in the border region construct a peripheral thin film transistor, and the pixel gate electrode, the first insulating layer, the active layer and the second metal layer located in the display region construct a pixel thin film transistor; forming a pixel electrode over the second metal layer; and forming an interference modulator (IMOD) over the pixel electrode.

A detailed description is given in the following embodiments with reference to the accompanying drawings.

### BRIEF DESCRIPTION OF THE DRAWING

For a more complete understanding of the present disclosure, and the advantages thereof, reference is now made to the following descriptions taken in conjunction with the accompanying drawings, in which:

FIG. 1 shows a cross-sectional view of a display device, in accordance with one embodiment of the disclosure.

FIGS. 2A-2L show cross-sectional views of various stages of forming a display device, in accordance with one embodiment of the disclosure.

### DETAILED DESCRIPTION

The following description is of the best-contemplated mode of carrying out the disclosure. This description is made for the purpose of illustrating the general principles of the disclosure and should not be taken in a limiting sense. The scope of the disclosure is best determined by reference to the appended claims.

It is understood that the following disclosure provides many different embodiments, or examples, for implementing different features of the invention. Specific examples of components and arrangements are described below to simplify the present disclosure. These are, of course, merely examples and are not intended to be limiting. In addition, the present disclosure may repeat reference numbers and/or letters in the various examples. This repetition is for the purpose of simplicity and clarity and does not in itself dictate a relationship between the various embodiments and/or configurations discussed. Furthermore, descriptions of a first layer “on,” “over,” (and like descriptions) a second layer, include embodiments where the first and second layers are in direct contact and those where one or more layers are interposing the first and second layers.

Moreover, use of ordinal terms such as “first”, “second”, “third”, etc., in the specification and claims to modify an element does not by itself connote any priority, precedence, or order of one claim element over another or the temporal order in which acts of a method are performed, but are used merely as labels to distinguish one claim element having a certain name from another element having the same name (but for use of the ordinal term) to distinguish the claim elements.

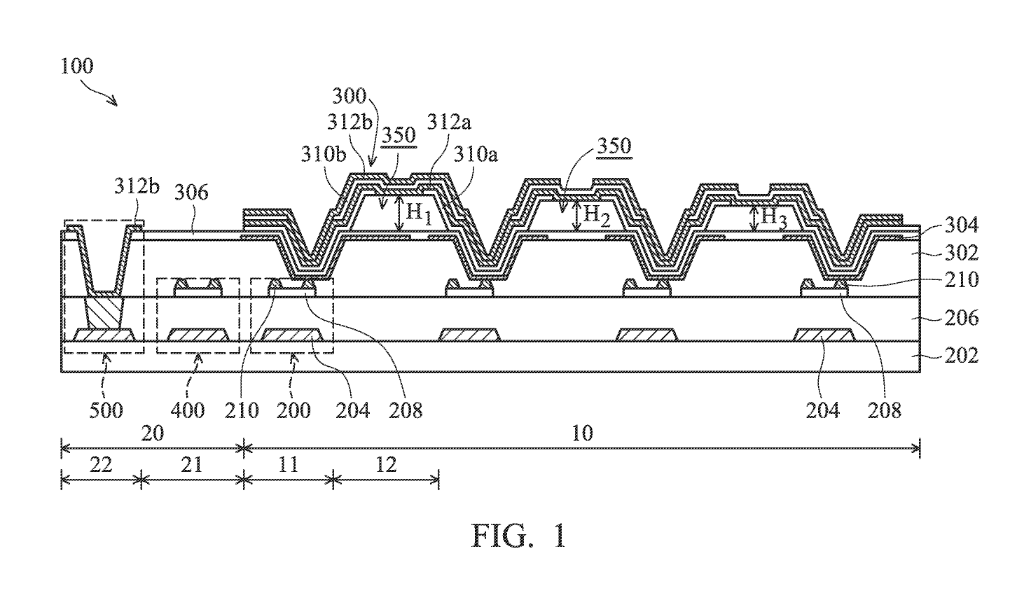

The disclosure provides a display device and method for fabricating the same. FIG. 1 shows a cross-sectional view of a display device 100, in accordance with one embodiment of the disclosure. The display device 100 is an active matrix interferometric modulator (IMOD) display device which includes a pixel thin film transistor 200 and an interferometric modulator (IMOD) 300.

The display device 100 includes a substrate 202, and the substrate 202 includes a display region 10 and a border region 20 outside the display region 10. The pixel thin film transistor 200 and the interferometric modulator (IMOD) 300 are located in the display region 10. A peripheral thin film transistor 400 and a wiring 500 are located in the border region 20.

The pixel thin film transistor 200 includes a first metal layer 204, a first insulating layer 206, an active layer 208 and a second metal layer 210. The first metal layer 204 in the display region 10 may also be used as a pixel gate electrode, and the second metal layer 210 in the display region 20 may also be used as a pixel source/drain electrode.

The interferometric modulator (IMOD) 300 includes a stationary layer 306, support layers 310a and 310b, movable reflective layers 312a and 312b, and an optical gap 350 between the stationary layer 306 and the movable reflective layer 312a.

As shown in FIG. 1, the color of the reflected light dependents on a height of the optical gap 350. In some embodiments, the display device 100 has at least three optical gaps 350 which respectively correspond to red (R), green (G) and blue (B) and respectively have different height H₁, H₂ and H₃. In some embodiments, the height H₁ is larger than the height H₂, and the height H₂ is larger than the height H₃.

The peripheral thin film transistor 400 includes the first metal layer 204, the first insulating layer 206, the active layer 208 and the second metal layer 210. The first metal layer 204 in the border region 20 may also be used as a peripheral gate electrode, and the second metal layer 210 in the border region 20 may also be used as a peripheral source/drain electrode.

The display region 10 includes a pixel driving region 11 and an aperture region 12 adjacent to the pixel driving region 11. The pixel thin film transistor 200 is located in the pixel driving region 11, and the optical gap 350 is located in the aperture region 12. The pixel thin film transistor 200 is adjacent to the optical gap 350, but does not overlap with the optical gap 350. Therefore, an aperture ratio is not affected because the optical gap 350 is not shielded by the pixel thin film transistor 200.

The border region 20 includes peripheral driving region 21 and a wiring region 22 adjacent to the peripheral driving region 21. The peripheral thin film transistor 400 is located in the peripheral driving region 21, the wiring 500 is located in the wiring region 22, and the first metal layer 204 is used as the wiring 500.

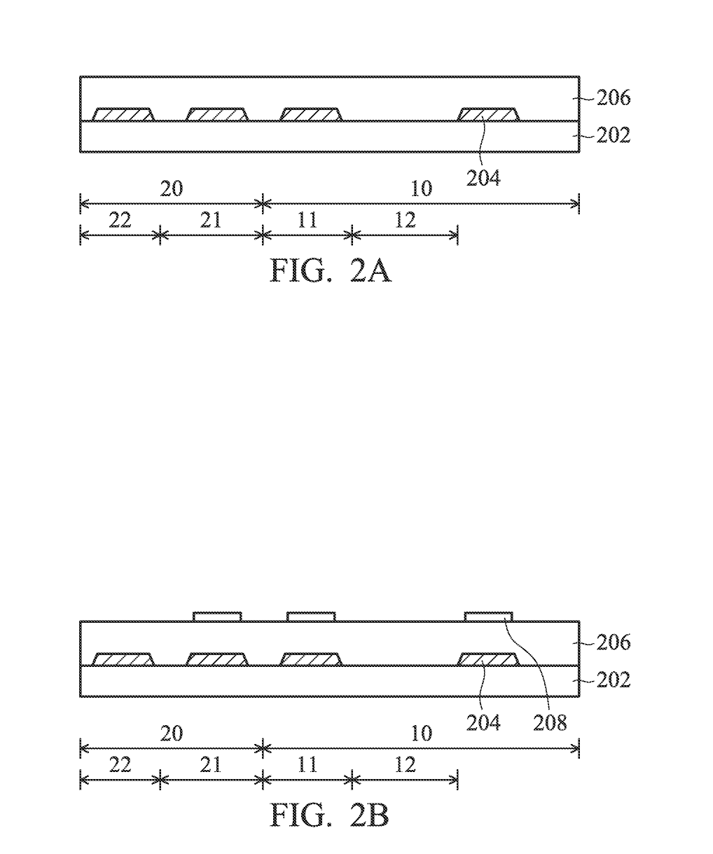

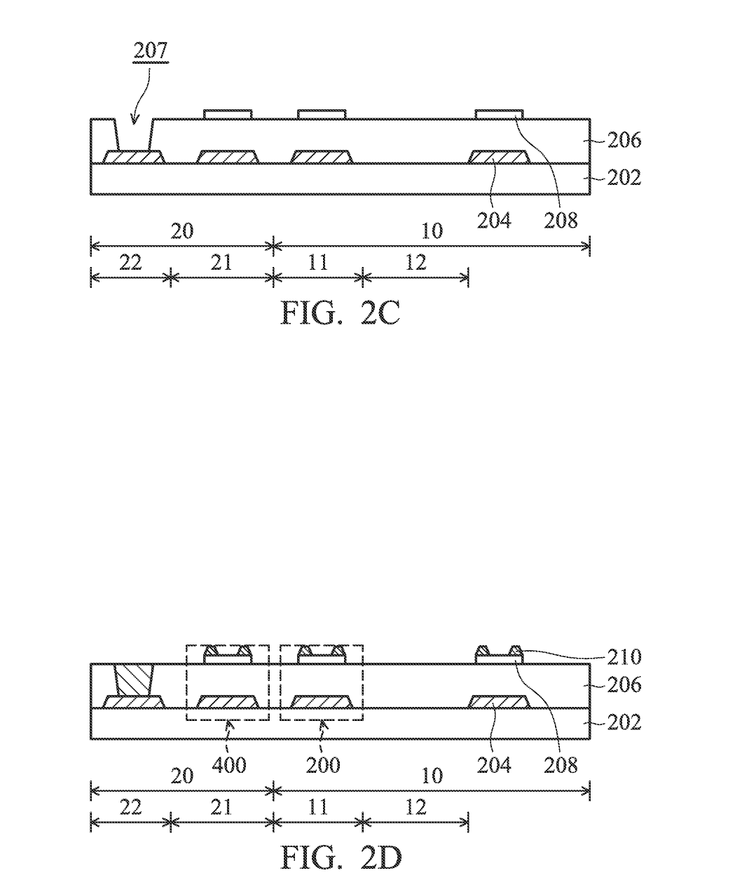

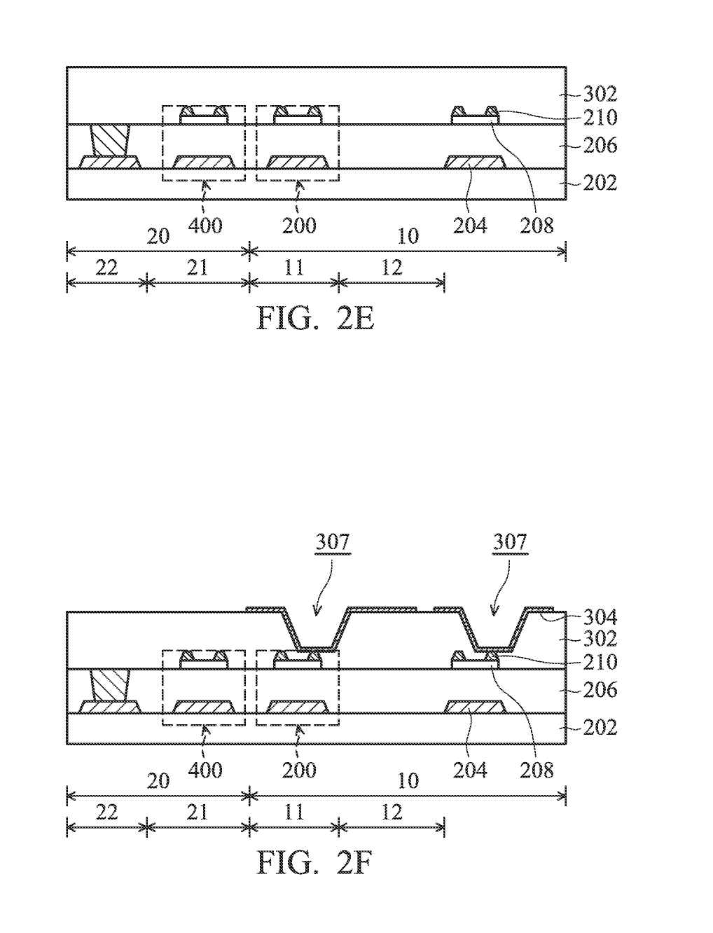

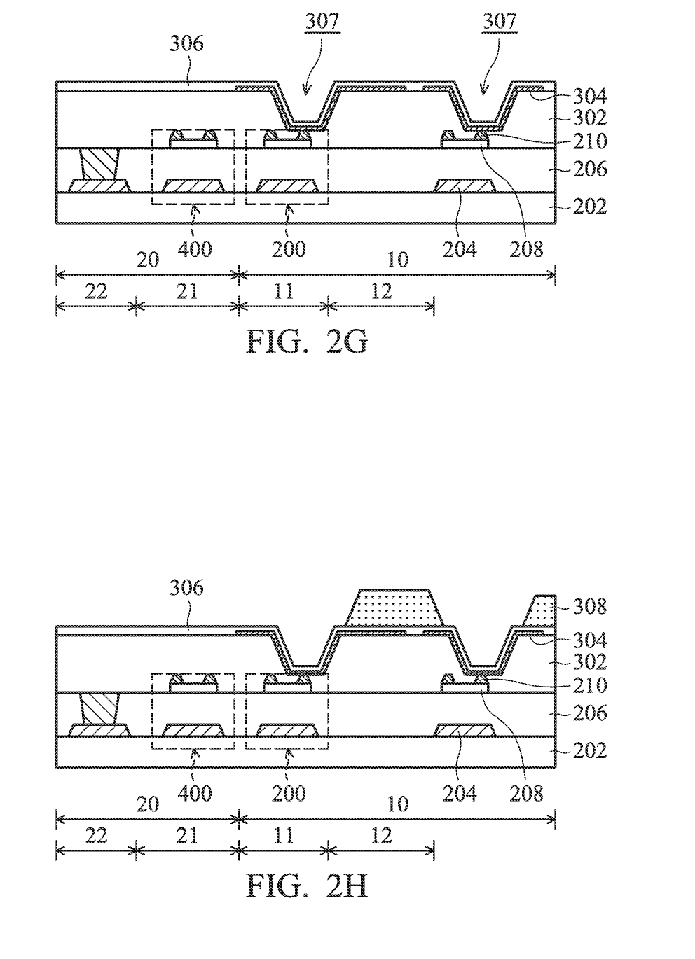

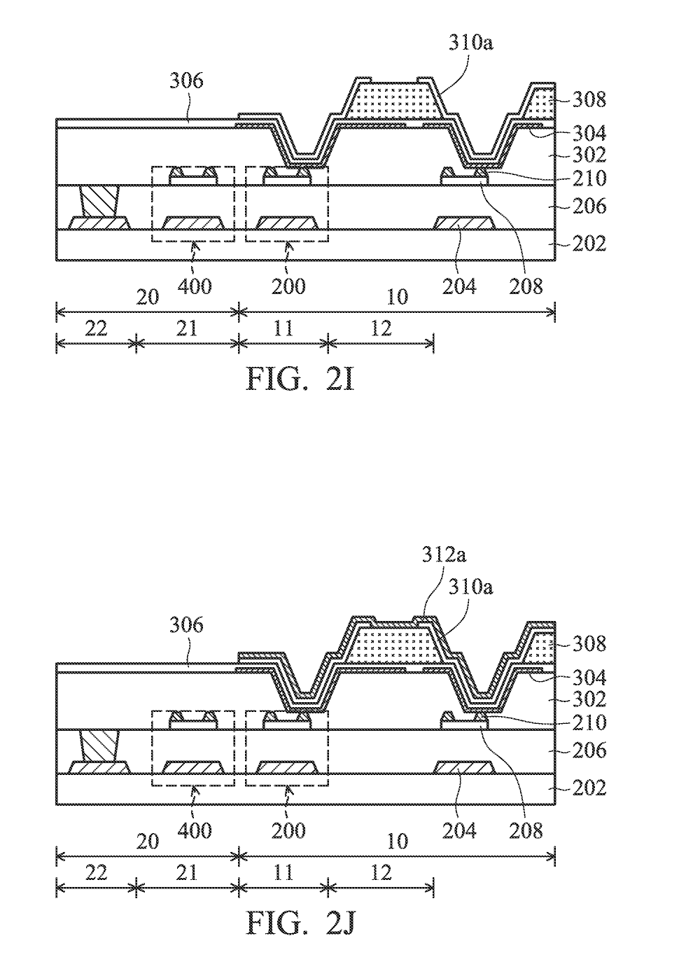

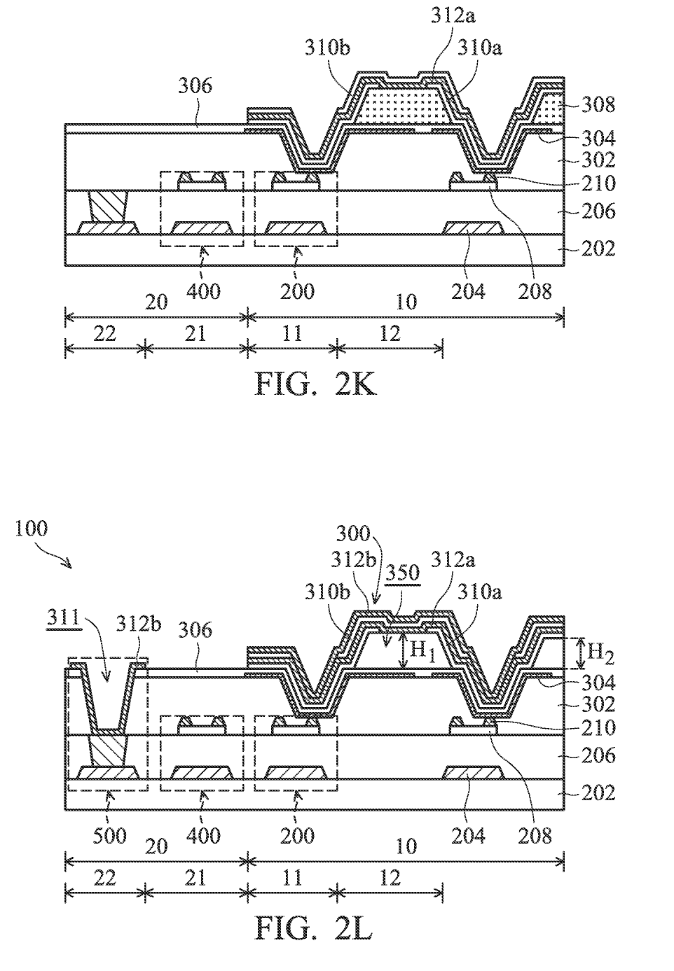

FIGS. 2A-2L show cross-sectional views of various stages of forming a display device, in accordance with one embodiment of the disclosure.

Referring to FIG. 2A, a substrate 202 is provided. The substrate 202 is made of transparent material including polyethylene terephthalate (PET), poly ether sulfones (PES), poly acrylate (PAR), polyethylene naphthalate (PEN), poly (p-phenylene sulfide) (PPS), polyallylate, polycarbonate (PC) or the like materials. In some embodiments, the substrate 202 is a hard substrate or flexible substrate. In some embodiments, the substrate 202 has planar, curved or another irregular shape.

The first metal layer 204 is formed over the substrate 202. The first metal layer 204 is made of molybdenum (Mo), aluminum (Al), copper (Cu), titanium (Ti), chromium (Cr), tantalum (Ta), alloy thereof or combinations thereof. In some embodiments, the first metal layer 204 is made of molybdenum (Mo)/aluminum (Al) dual-layer.

In some embodiments, the first metal layer 204 is formed by depositing a metal material by a deposition process and then using a photolithography patterning process and etching process. The deposition process includes physical vapor deposition (PVD) process, chemical vapor deposition (CVD) process, or other applicable processes. The photolithography patterning process includes photoresist coating (e.g., spin-on coating), soft baking, mask aligning, exposure, post-exposure baking, developing the photoresist, rinsing, drying (e.g., hard baking), other suitable processes, and/or combinations thereof. The etching process includes dry etching, wet etching, and/or other etching methods (e.g., reactive ion etching).

It should be noted that a portion of the first metal layer 204 in the display region 10 is used as the pixel gate electrode and the light-shielding pattern, and another portion of the first metal layer 204 in the border region 20 is used as the peripheral gate electrode and the wiring. Therefore, the pixel gate electrode is level with the light-shielding pattern. In prior art, the pixel electrode and the light-shielding pattern are formed by separate steps. Compared with the prior art, the first metal layer of the disclosure is simultaneously used as the pixel electrode and the light-shielding pattern. Therefore, the fabricating steps of the disclosure are reduced, and fabricating time and cost both are further saved.

After the first metal layer 204 is formed, the first insulating layer 206 is formed over the first metal layer 204 and over the substrate 202. The first insulating layer 206 is made of silicon oxide, silicon nitride, silicon oxynitride or combinations thereof. In some embodiments, the first insulating layer 206 is made of silicon oxide.

Referring to FIG. 2B, after the first insulating layer 206 is formed, the active layer 208 is formed over the first insulating layer 206. The active layer 208 is made of amorphous-silicon (a-si), low-temperature polysilicon (LTPS), indium gallium zinc oxide, (IGZO), indium zinc oxide (IZO) or combinations thereof.

Referring to FIG. 2C, the via hole 207 through the first insulating layer 206 is formed in the wiring region 22. The position of the via hole 207 is used to fill the conductive materials to transport the signal from the display region 10 or the peripheral driving region 21 to the outer device.

Referring to FIG. 2D, in the display region 10 and the border region 20, the second metal layer 210 is formed over the active layer 208. The second metal layer is made of molybdenum (Mo), aluminum (Al), tantalum (Ta), tungsten (W), titanium (Ti), copper (Cu), alloy thereof or combinations thereof. In some embodiments, the second metal layer 210 is made of molybdenum (Mo)/aluminum (Al)/molybdenum (Mo) tri-layer. In some embodiments, the second metal layer 210 is made of titanium (Ti)/aluminum (Al)/titanium (Ti) tri-layer. In the wiring region 22, the second metal layer is formed in the via hole 207.

In the display region 10, a portion of the second metal layer 210 is used as the pixel source/drain (S/D) electrode, and in the peripheral driving region 21, another portion of the second metal layer 210 is used as the peripheral source/drain (S/D) electrode. Therefore, the pixel source/drain (S/D) electrode is level with the peripheral source/drain (S/D) electrode.

It should be noted that the pixel thin film transistor 200 in the display region 10 is made of pixel gate electrode which is made by the fist metal layer 204, the first insulating layer 206, the active layer 208 and the second metal layer 210. A peripheral thin film transistor 400 is made of the peripheral gate electrode which is made by the first metal layer 204, the first insulating layer 206, the active layer 208 and the second metal layer 210.

Referring to FIG. 2E, a second insulating layer 302 is formed over the second metal layer 210 and the first insulating layer 206. The material of the second insulating layer 302 includes inorganic or organic materials, such as silicon oxide, silicon nitride, silicon oxynitride, photoresist or combinations thereof. In some embodiments, the first insulating layer 206 and the second insulating layer 302 are made of the same material, for example, both are made of silicon oxide (SiOx).

Referring to FIG. 2F, after the second insulating layer 302 is formed, an opening 307 is formed through the second insulating layer 302 to expose the second metal layer 210. Afterwards, a pixel electrode 304 is confromally formed along the opening 307, and it is formed to contact the second metal layer 210.

The pixel electrode 304 is made of half-transparent half-reflective material, such as molybdenum (Mo) or chromium (Cr). In some embodiments, the pixel electrode 304 is made of MoCr alloy.

Referring to FIG. 2G, after the pixel electrode 304 is formed, a stationary layer 306 is conformally formed over the pixel electrode 304 and the second insulating layer 302. The stationary layer 306 may include a single layer or multiple layers. The material of the stationary layer 306 is made of silicon oxide (SiOx), aluminum oxide (AlOx) or combinations thereof. In some embodiments, the stationary layer 306 is made of silicon oxide (SiOx)/aluminum oxide (AlOx) dual-layer structure.

Referring to FIG. 2H, after the stationary layer 306 is formed, a sacrificial layer 308 is formed over the stationary layer 306 and the second insulating layer 302. The material of the sacrificial layer 308 includes molybdenum (Mo), amorphous silicon, or another etchable material. In the following steps, when the sacrificial layer 308 is removed, an optical gap is formed. Therefore, as shown in FIG. 1, in order to obtain the optical gap with different heights, the thickness of the sacrificial layer 308 may be designed according to actual application needs.

Referring to FIG. 21, after the sacrificial layer 308 is formed, a first support layer 310a is formed over the stationary layer 306 and a portion of the sacrificial layer 308. The material of the first support layer 310a includes silicon oxide (SiOx), silicon oxynitride (SiON) or combinations thereof. In some embodiments, the first support layer 310a may include a single layer or multiple layers. In some embodiments, the first support layer 310a is made of silicon oxide (SiOx)/silicon oxynitride (SiON) dual-layer.

Referring to FIG. 2J, after the first support layer 310a is formed, a first movable reflective layer 312a is formed over the first support layer 310a and the sacrificial layer 308. The material of the first movable reflective layer 312a includes aluminum (Al), copper (Cu), chromium (Cr), alloy thereof or combinations thereof. In some embodiments, the first movable reflective layer 312a is made of AlCu alloy.

Referring to FIG. 2K, a second support layer 310b is formed over a portion of the movable reflective layer 312a to expose a portion of movable reflective layer 312a. The material of the second support layer 310b includes silicon oxide (SiOx), silicon oxynitride (SiON) or combinations thereof. In some embodiments, the second support layer 310b may include a single layer or multiple layers. In some embodiments, the first support layer 310a and the second support layer 310b both are made of silicon oxide (SiOx)/silicon oxynitride (SiON) dual-layer.

Referring to FIG. 2L, a second movable reflective layer 312b is conformally formed over the second support layer 310b. The second movable reflective layer 312b electrically connects with the exposed first movable reflective layer 312a. In some embodiments, the second movable reflective layer 312b is made of AlCu alloy.

Furthermore, in the wiring region 22, a hole 311 is formed through the second insulating layer 302 and the second movable reflective layer 312b is formed along the shape of the hole 311.

Afterwards, an etching process is performed to remove the sacrificial layer 308 and leave the optical gap 350. In some embodiments, the etching process including fluorine (F)-containing etchant (such as XeF₂) is used to remove the sacrificial layer 308. An interference modulator (IMOD) 300 is constructed by the stationary layer 306, the first support layers 310a, the second support layer 310b, the first movable reflective layer 312a, the second movable reflective layer 312b, and the optical gap 350. As a result, the display device 100 is formed.

It should be noted that the pixel thin film transistor 200 is not below the optical gap 350, and therefore the aperture ratio of the display device 100 is improved.

The disclosure provides a display device and a method for fabricating the same. The display device is an active matrix interference modulator (IMOD) display device which includes a thin film transistor and an interference modulator (IMOD). The interference modulator (IMOD) is integrated on the thin film transistor, a first metal layer of the disclosure is simultaneously used as a light-shielding pattern and a gate electrode, and a second metal layer is simultaneously used as a wiring and a source/drain metal layer. Therefore, the fabricating time and cost are saved. In addition, the aperture ratio of the display device is improved because the pixel thin film transistor is not below an optical gap.

In some embodiments, a display device is provided. The display device includes a substrate, wherein the substrate comprises a display region and border region outside the display region; a light-shielding pattern, located in the display region; a pixel thin film transistor, located in the display region and comprising: a pixel gate electrode; a first insulating layer, disposed over the pixel gate electrode; an active layer, disposed over the first insulating layer; and a second metal layer, disposed over the active layer; a wiring, located in the border region; a peripheral thin film transistor located in the border region and comprising: a peripheral gate electrode; the first insulating layer disposed over the peripheral gate electrode; the active layer, disposed over the first insulating layer; and the second metal layer, disposed over the active layer; wherein the light-shielding pattern, the pixel gate electrode, the wiring and the peripheral gate electrode are made by a first metal layer; a pixel electrode, disposed over the second metal layer and located in the display region; and an interference modulator (IMOD), disposed over the pixel electrode.

In some embodiments, a method for fabricating the display device is provided. The method includes providing a substrate, wherein the substrate comprises a display region and a border region outside the display region; forming a first metal layer in the display region and the border region, wherein the first metal layer in the border region is used as a peripheral gate electrode and a wiring, and the first metal layer in the display region is used as a pixel gate electrode and a light-shielding pattern; forming a first insulating layer over the first metal layer; forming an active layer over the first insulating layer; forming a second metal layer over the active layer, wherein the peripheral gate electrode, the first insulating layer, the active layer and the second metal layer located in the border region construct a peripheral thin film transistor, and the pixel gate electrode, the first insulating layer, the active layer and the second metal layer located in the display region construct a thin film transistor; forming a pixel electrode over the second metal layer; and forming an interference modulator (IMOD) over the pixel electrode.

While the disclosure has been described by way of example and in terms of the preferred embodiments, it is to be understood that the disclosure is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A display device, comprising:
a substrate, wherein the substrate comprises a display region and a border region outside the display region;
a light-shielding pattern, located in the display region;
a pixel thin film transistor, located in the display region and comprising:
a pixel gate electrode;
a first insulating layer, disposed over the pixel gate electrode;
an active layer, disposed over the first insulating layer; and
a second metal layer, disposed over the active layer;
a wiring, located in the border region;
a peripheral thin film transistor located in the border region and comprising:
a peripheral gate electrode;
the first insulating layer disposed over the peripheral gate electrode;
the active layer, disposed over the first insulating layer; and
the second metal layer, disposed over the active layer;
wherein the light-shielding pattern, the pixel gate electrode, the wiring and the peripheral gate electrode are made by a first metal layer;
a pixel electrode, disposed over the second metal layer and located in the display region; and
an interference modulator (IMOD), disposed over the pixel electrode.

2. The display device as claimed in claim 1, wherein the interference modulator (IMOD) comprises:
a stationary layer, disposed over the pixel electrode;
a support layer, disposed over the stationary layer;
a movable reflective layer, disposed over the support layer, wherein an optical gap is between the stationary layer and the movable reflective layer.

3. The display device as claimed in claim 2, wherein the display region comprises a pixel driving region and an aperture region adjacent to the pixel driving region, the pixel thin film transistor is located in the pixel driving region and the optical gap is located in the aperture region.

4. The display device as claimed in claim 3, wherein the pixel thin film transistor does not overlap with the optical gap.

5. The display device as claimed in claim 1, wherein the border region comprises a peripheral driving region and a wiring region adjacent to the peripheral driving region, the peripheral thin film transistor is located in the peripheral driving region, and the wiring is located in the wiring region.

6. The display device as claimed in claim 2, wherein the display device has at least three optical gaps which respectively have different heights.

7. The display device as claimed in claim 1, wherein the pixel gate electrode is level with the light-shielding pattern.

8. A method for fabricating the display device, comprising:
providing a substrate, wherein the substrate comprises a display region and a border region outside the display region;
forming a first metal layer in the display region and the border region, wherein the first metal layer in the border region is used as a peripheral gate electrode and a wiring, and the first metal layer in the display region is used as a pixel gate electrode and a light-shielding pattern;
forming a first insulating layer over the first metal layer;
forming an active layer over the first insulating layer;
forming a second metal layer over the active layer, wherein the peripheral gate electrode, the first insulating layer, the active layer and the second metal layer located in the border region construct a peripheral thin film transistor, and the pixel gate electrode, the first insulating layer, the active layer and the second metal layer located in the display region construct a pixel thin film transistor;
forming a pixel electrode over the second metal layer; and
forming an interference modulator (IMOD) over the pixel electrode.

9. The method for fabricating the display device as claimed in claim 8, further comprising:
after forming the second metal layer over the active layer, forming a second insulating layer over the first insulating layer and over the second metal layer;
forming an opening through the second insulating layer to expose the second metal layer; and
forming the pixel electrode along the opening, wherein the pixel electrode is formed to contact the second metal layer.

10. The method for fabricating the display device as claimed in claim 9, wherein forming the interference modulator (IMOD) on the pixel electrode comprises:
forming a stationary layer over the pixel electrode and over the second insulating layer;
forming a sacrificial layer over the stationary layer and over the second insulating layer;
forming a support layer over the stationary layer and over the sacrificial layer; and
forming a movable reflective layer over the support layer and over the sacrificial layer.

11. The method for fabricating the display device as claimed in claim 10, further comprising:
removing the sacrificial layer to form an optical gap between the stationary layer and the movable reflective layer.

12. The method for fabricating the display device as claimed in claim 11, wherein the pixel thin film transistor does not overlap with the optical gap.

13. The method for fabricating the display device as claimed in claim 8, wherein the pixel gate electrode is level with the light-shielding pattern.
